(19) United States
(12) Patent Application Publication
(10) Pub. No.: US 2025/0393190 A1
(43) Pub. Date: Dec. 25, 2025

(54) SEMICONDUCTOR STRUCTURE, SEMICONDUCTOR DEVICE, AND METHOD FOR MANUFACTURING SEMICONDUCTOR STRUCTURE

(71) Applicant: CXMT Corporation, Hefei City (CN)

(72) Inventors: Yanghao LIU, Hefei City (CN); Penghui XU, Hefei City (CN); Guoxu YIN, Hefei City (CN); Tao LIU, Hefei City (CN); Kun XUE, Hefei City (CN); Ning WANG, Hefei City (CN)

(73) Assignee: CXMT Corporation, Hefei City (CN)

(21) Appl. No.: 18/950,124

(22) Filed: Nov. 17, 2024

Related U.S. Application Data
(63) Continuation of application No. PCT/CN2024/119986, filed on Sep. 20, 2024.

(30) Foreign Application Priority Data
Jun. 21, 2024 (CN) 202410816506.3

(51) Int. Cl. H10B 12/00; H01L 23/00; H01L 25/18; H10B 80/00

(52) U.S. Cl. CPC H10B 12/315; H10B 12/0335; H01L 24/05; H01L 24/08; H01L 24/80; H01L 25/18; H01L 2224/05557; H01L 2224/05558; H01L 2224/08145; H01L 2224/80895; H01L 2224/80896; H01L 2924/1436; H10B 80/00

(57) ABSTRACT

A semiconductor structure includes: a substrate, a plurality of active pillars, first recesses, first insulating layers; and capacitor contact structures; wherein the capacitor contact structures include metal silicide layers, diffusion barrier layers, and metal layers that are sequentially arranged in an extension direction of the plurality of active pillars, the metal silicide layers are in contact with the plurality of active pillars, and top surfaces of the diffusion barrier layers are lower than top surfaces of the first recesses.

### CROSS-REFERENCE TO RELATED APPLICATIONS

This application is a continuation of International Patent Application No. PCT/CN2024/119986 filed on Sep. 20, 2024, which claims priority to Chinese Patent Application No. 202410816506.3 filed on Jun. 21, 2024. The disclosures of the above-referenced applications are hereby incorporated by reference in their entirety.

### BACKGROUND

A dynamic random access memory (DRAM) is a volatile memory, and is composed of a plurality of memory cells. Each of the plurality of memory cells mainly includes a transistor and a capacitor structure, and the plurality of memory cells are electrically connected to each other through word lines (WLs) and bit lines (BLs).

With the development of semiconductor technologies, an architecture scheme of changing a horizontal transistor to a vertical channel transistor has been proposed. In the DRAM, active pillars extending vertically are formed on a substrate, surrounding gates are formed outside the active pillars, and buried bit lines and buried word lines are formed.

However, the DRAM with the vertical channel transistors still faces many problems, such as the electrical connection between the capacitor structures and the active pillars, and the contamination of an etching chamber during the etching of capacitor holes, which have become urgent technical problems to be solved.

It should be noted that the information disclosed in the above background section is only used for enhancement of understanding of the background of the present disclosure and therefore may include information that does not constitute some implementations known to those of ordinary skill in the art.

### SUMMARY

The present disclosure relates to the technical field of semiconductors, in particular to a semiconductor structure, a semiconductor device, and a method for manufacturing the semiconductor structure.

The present disclosure provides a semiconductor structure, a semiconductor device, and a method for manufacturing the semiconductor structure. The semiconductor structure can reduce contact resistance between a capacitor structure and an active pillar and avoid the contamination of an etching chamber during the etching of capacitor holes.

Additional features and advantages of the present disclosure will become apparent from the detailed description below, or will be learned in part by practice of the present disclosure.

According to one aspect of the present disclosure, a semiconductor structure is provided. The semiconductor structure includes:
a substrate, where a plurality of active pillars spaced apart from each other along a first direction and a second direction are arranged in the substrate, the plurality of active pillars extend along a third direction, first recesses exposing top surfaces of the plurality of active pillars are formed in the substrate, the first recesses are spaced apart from each other along the first direction and the second direction, first insulating layers are arranged in the substrate, the first insulating layers isolate the first recesses, the first direction intersects with the second direction, and both the first direction and the second direction are perpendicular to the third direction; and
capacitor contact structures, where the capacitor contact structures are located in the first recesses, and the capacitor contact structures cover the top surfaces of the plurality of active pillars for connection to capacitor structures, and
where the capacitor contact structures include metal silicide layers, diffusion barrier layers, and metal layers that are sequentially arranged in an extension direction of the plurality of active pillars, the metal silicide layers are in contact with the plurality of active pillars, and top surfaces of the diffusion barrier layers are lower than top surfaces of the first recesses.

According to another aspect of the present disclosure, a semiconductor device is provided. The semiconductor device is obtained by bonding the above semiconductor structure to a first wafer, the first wafer being provided with CMOS transistors of the semiconductor device.

According to yet another aspect of the present disclosure, a method for manufacturing the above semiconductor structure is provided. The method includes:
providing a substrate, and forming a plurality of initial active pillars spaced apart from each other along a first direction and a second direction in the substrate, where the plurality of initial active pillars extend along a third direction, first initial insulating layers for isolating the plurality of initial active pillars are formed in the substrate, the first direction intersects with the second direction, and both the first direction and the second direction are perpendicular to the third direction;
etching the plurality of initial active pillars to form initial recesses, where the initial recesses are spaced apart from each other along the first direction and the second direction, the initial recesses are isolated by the first initial insulating layers, and the etched plurality of initial active pillars serve as active pillars;
sequentially forming metal silicide layers, diffusion barrier material layers, and metal material layers in the initial recesses, where the diffusion barrier material layers are further formed on side walls of the initial recesses;
etching the first initial insulating layers to expose the diffusion barrier material layers on the side walls of the initial recesses;
etching the diffusion barrier material layers, such that top surfaces of the diffusion barrier material layers are lower than top surfaces of the initial recesses, where the etched diffusion barrier material layers serve as diffusion barrier layers, the etched metal material layers serve as metal layers, and the metal silicide layers, the diffusion barrier layers, and the metal layers form capacitor contact structures for connection to capacitor structures; and
forming second insulating layers, such that the etched first initial insulating layers and the second insulating layers form first insulating layers, where the initial recesses filled with the first insulating layers are defined as first recesses.

It should be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the specification, illustrate embodiments consistent with the present disclosure and, together with the specification, serve to explain the principles of the present disclosure. It is apparent that the drawings in the description below are only some embodiments of the present disclosure, and for those of ordinary skill in the art, other drawings can be obtained according to the drawings without creative efforts.

FIG. 1 is a top perspective view of a substrate of a semiconductor structure according to one embodiment of the present disclosure.

FIG. 2 illustrates cross-sectional views at a-a and c-c of a semiconductor structure in one embodiment corresponding to FIG. 1.

FIG. 3 illustrates cross-sectional views at a-a and c-c of a semiconductor structure in another embodiment corresponding to FIG. 1.

FIG. 4 illustrates enlarged views of capacitor contact structures in semiconductor structures in different embodiments.

FIG. 5 illustrates a schematic structural view of a semiconductor device according to one embodiment of the present disclosure.

FIG. 6 illustrates a flowchart of steps for a method for manufacturing a semiconductor structure according to one embodiment of the present disclosure.

FIG. 7 is a first cross-sectional view at a-a and c-c in FIG. 1 in the process of forming a corresponding semiconductor structure in some embodiments of the present disclosure.

FIG. 8 is a second cross-sectional view at a-a and c-c in FIG. 1 in the process of forming a corresponding semiconductor structure in some embodiments of the present disclosure.

FIG. 9 is a third cross-sectional view at a-a and c-c in FIG. 1 in the process of forming a corresponding semiconductor structure in some embodiments of the present disclosure.

FIG. 10 is a fourth cross-sectional view at a-a and c-c in FIG. 1 in the process of forming a corresponding semiconductor structure in some embodiments of the present disclosure.

FIG. 11 is a fifth cross-sectional view at a-a and c-c in FIG. 1 in the process of forming a corresponding semiconductor structure in some embodiments of the present disclosure.

FIG. 12 is a sixth cross-sectional view at a-a and c-c in FIG. 1 in the process of forming a corresponding semiconductor structure in some embodiments of the present disclosure.

FIG. 13 is a seventh cross-sectional view at a-a and c-c in FIG. 1 in the process of forming a corresponding semiconductor structure in some embodiments of the present disclosure.

FIG. 14 is an eighth cross-sectional view at a-a and c-c in FIG. 1 in the process of forming a corresponding semiconductor structure in some embodiments of the present disclosure.

FIG. 15 is a ninth cross-sectional view at a-a and c-c in FIG. 1 in the process of forming a corresponding semiconductor structure in some embodiments of the present disclosure.

FIG. 16 is a tenth cross-sectional view at a-a and c-c in FIG. 1 in the process of forming a corresponding semiconductor structure in some embodiments of the present disclosure.

FIG. 17 is an eleventh cross-sectional view at a-a and c-c in FIG. 1 in the process of forming a corresponding semiconductor structure in some embodiments of the present disclosure.

### DETAILED DESCRIPTION

To facilitate an understanding of the present disclosure, the present disclosure will be more fully described below with reference to the accompanying drawings. Preferred embodiments of the present disclosure are shown in the accompanying drawings. The present disclosure may, however, be implemented in many different forms and should not be construed as being limited to the embodiments described herein. Rather, these embodiments are provided so that the disclosed content of the present disclosure will be more thorough and complete.

The size of transistor cells integrated on a substrate of a semiconductor device is gradually reduced, such that a vertical channel transistor of a 4F2 (F denotes a minimum feature size) architecture with a vertical channel is proposed. The area of the vertical channel transistor cell of the 4F2 architecture can be reduced by about 30% as compared to a planar transistor of a 6F2 architecture.

However, in an existing semiconductor structure with the vertical channel transistor, the contact resistance between an active pillar and a capacitor structure of the vertical channel transistor is high, which limits the transmission rate of the vertical channel transistor and affects the performance of the semiconductor structure. Meanwhile, in the process of manufacturing the semiconductor structure, especially in the etching process of capacitor holes, the structure of the early-stage process affects the precision of the etching chamber in the process of etching the capacitor holes.

In view of this, the embodiments of the present disclosure provide a semiconductor structure, a semiconductor device, and a method for manufacturing the semiconductor structure. In the semiconductor structure, capacitor contact structures are arranged between active pillars and capacitor structures, and the capacitor contact structures include metal silicide layers, diffusion barrier layers, and metal layers, such that the resistance between the capacitor structures and the active pillars is reduced, which improves the transmission rate of the vertical channel transistor. Meanwhile, a height of orthographic projections of the diffusion barrier layers on side walls of first recesses in a third direction is set to be smaller than a height of orthographic projections of the metal layers on the side walls of the first recesses in the third direction, thereby avoiding the contamination of an etching chamber during the etching of capacitor holes.

To make the objectives, technical solutions, and advantages of the embodiments of the present disclosure clearer, the technical solutions in the embodiments of the present disclosure will be clearly and completely described below with reference to the drawings in the embodiments of the present disclosure. It is evident that the described embodiments are some, but not all embodiments of the present disclosure. On the basis of the embodiments of the present disclosure, all other embodiments obtained by those of ordinary skill in the art without creative efforts shall fall within the protection scope of the present disclosure.

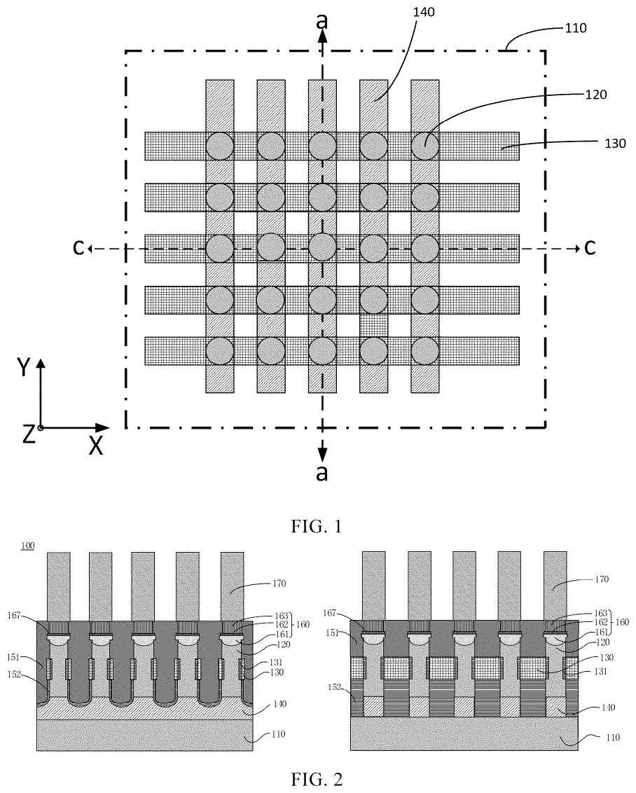

FIG. 1 is a top perspective view of a substrate of a semiconductor structure according to one embodiment of the present disclosure; FIG. 2 illustrates cross-sectional views at a-a and c-c of a semiconductor structure in one embodiment corresponding to FIG. 1.

Referring to FIG. 1, in one embodiment, a semiconductor structure 100 includes:
a substrate 110, where a plurality of active pillars 120 spaced apart from each other along a first direction and a second direction are formed in the substrate 110, the plurality of active pillars 120 extend along a third direction, first recesses 167 exposing top surfaces of the active pillars 120 are arranged in the substrate 110, the first recesses 167 are spaced apart from each other along the first direction and the second direction, first insulating layers 151 are further arranged in the substrate 110, the first insulating layers 151 isolate the first recesses 167, the first direction intersects with the second direction, and both the first direction and the second direction are perpendicular to the third direction.

With further reference to FIG. 1, exemplarily, the first direction and the second direction may be perpendicular to each other, the first direction is, for example, the Y direction in FIG. 1, the second direction is, for example, the X direction in FIG. 1, and the third direction is, for example, the Z direction in FIG. 1, i.e., the thickness direction of the substrate 110. In other embodiments, the first direction and the second direction may not be perpendicular to each other. For example, an included angle between the first direction and the second direction may be an acute angle. The substrate 110 may be made of, for example, monocrystalline silicon, polycrystalline silicon, amorphous silicon, or silicon-on-insulator (SOI). In addition, the substrate 110 may be made of silicon germanium, silicon germanium-on-insulator (SGOI), indium antimonide, lead telluride compound, indium arsenide, indium phosphide, gallium arsenide, or gallium antimonide, but is not limited thereto. The plurality of active pillars 120 in the substrate 110 are spaced apart in an array and extend in the thickness direction of the substrate 110, i.e., the Z direction. The cross sections of the plurality of active pillars 120 may be circular, square, oval, or the like, so as to improve the integration of the semiconductor structure 100, without being limited thereto. The plurality of active pillars 120 are used for forming a channel region (not shown), a source region (not shown), and a drain region (not shown) of a vertical channel transistor.

With further reference to FIGS. 1 and 2, the first recesses 167 expose the top surfaces of the active pillars 120, that is, each active pillar corresponds to one first recess, that is, both the first recesses and the active pillars are spaced apart from each other along the first direction and the second direction, and the shape of the first recesses may be circular, elliptical, polygonal, or the like from a top view, which is not specifically limited and may be reasonably set according to practical situations. The first insulating layers 151 isolate not only the first recesses 167 but also the active pillars 120, and the first insulating layers 151 may be made of silicon oxide, silicon nitride, silicon oxynitride, silicon oxycarbide, or silicon carbonitride. In this embodiment, the first insulating layers 151 are made of silicon nitride, and the silicon nitride is low-density silicon nitride, so as to reduce the stress of the first insulating layers 151 on the active pillars 120.

For the capacitor contact structures 160, referring to FIG. 2, the capacitor contact structures 160 are located in the first recesses 167, and the capacitor contact structures 160 cover the top surfaces of the active pillars 120 for connection to capacitor structures 170, that is, the spatial size of the capacitor contact structures 160 defines the spatial size of the first recesses 167.

With further reference to FIG. 2, the capacitor contact structures 160 include metal silicide layers 161, diffusion barrier layers 162, and metal layers 163 sequentially laminated in the extension direction of the active pillars 120, the metal silicide layers 161 are in contact with the active pillars 120, and top surfaces of the diffusion barrier layers 162 are lower than top surfaces of the first recesses 167.

The metal silicide layers 161 are made of a compound formed by reacting a metal element (e.g., titanium, tungsten, nickel, cobalt, and molybdenum) with silicon, and the formation of the metal silicide produces a direct metal-semiconductor contact. The contact reduces the interface state, reduces the contact resistance, and improves the current transmission efficiency. Meanwhile, the metal silicide has good adhesion with the active pillars and the metal diffusion layers, which is beneficial to forming stable contact, reducing interface resistance, and improving the reliability of the whole circuit. Common metal silicides include titanium silicide (TiSi₂), tungsten silicide (WSi₂), nickel silicide (NiSi), cobalt silicide (CoSi₂), and the like. The diffusion barrier layers 162 may prevent the metal layers 163 from diffusing into the metal silicide layers 161, which may affect the electrical performance of the metal silicide layers 161. The diffusion barrier layers 162 are made of a compound of metal titanium, such as titanium nitride (TiN), which has a high melting point and chemical stability, and can maintain its structural integrity at high temperatures, thereby effectively preventing the diffusion of metals into areas where their presence is undesirable. The metal layers 163 are mainly made of a metal material, such as aluminum (Al), copper (Cu), and tungsten (W), which have low resistivity and can transmit current efficiently. Moreover, the top surfaces of the diffusion barrier layers 162 are lower than the top surfaces of the first recesses 167, where the top surfaces of the diffusion barrier layers 162 are planes with the maximum height of the diffusion barrier layers 162 in the third direction, that is, the diffusion barrier layers 162 are not exposed to the top surfaces of the first recesses 167, such that the diffusion barrier layers 162 are not etched in the process of etching capacitor holes, thereby avoiding titanium contamination of the etching chamber and improving the etching performance when etching the capacitor holes.

By sequentially arranging the metal silicide layers 161, the diffusion barrier layers 162, and the metal layers 163, the contact resistance between the active pillars and the capacitor structures of the vertical channel transistor can be effectively reduced, which improves the transmission rate of the vertical channel transistor. Meanwhile, the top surfaces of the diffusion barrier layers 162 are set to be lower than the top surfaces of the first recesses 167, such that titanium contamination of the etching chamber can be avoided in the process of etching the capacitor holes, thereby improving the etching precision.

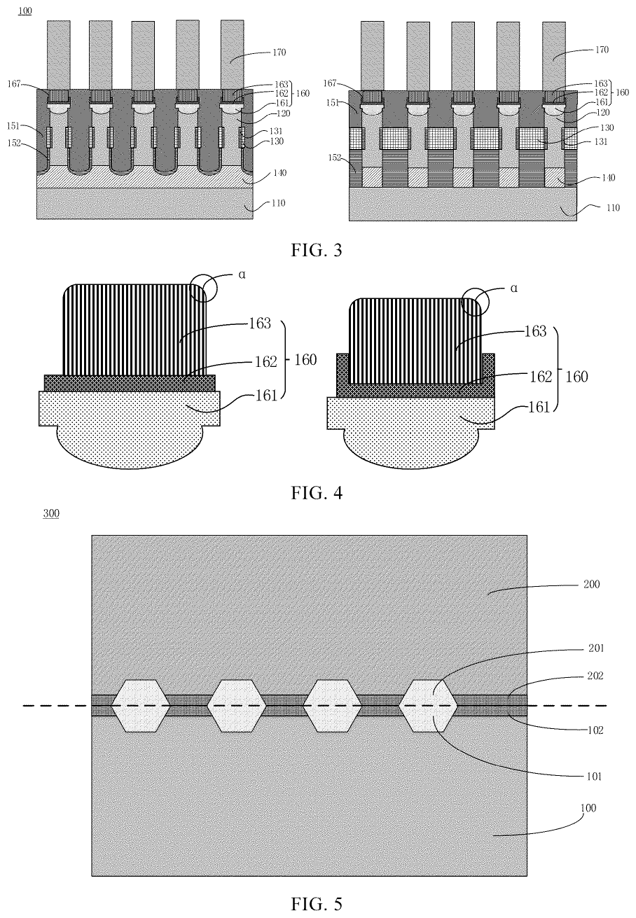

FIG. 3 illustrates cross-sectional views at a-a and c-c of a semiconductor structure in another embodiment corresponding to FIG. 1.

Referring to FIG. 3, in one embodiment, the diffusion barrier layers 162 are further arranged on side walls of the first recesses 167, and a height of the diffusion barrier layers 162 on the side walls of the first recesses 167 in the third direction is smaller than a height of the metal layers 163 in the third direction. That is, the diffusion barrier layers 162 wrap portions of the metal layers 163, and thus, orthographic projection areas of the diffusion barrier layers 162 on the substrate are larger than orthographic projection areas of the metal layers 163 on the substrate, and the diffusion barrier layers 162 are not exposed to the top surfaces of the first recesses, such that titanium contamination of the etching chamber can be avoided in the process of etching the capacitor holes, and the size of the contact structures 160 can be reduced, which can reduce the risk of short circuit of the contact structures 160. In addition, the contact area between the diffusion barrier layers 162 and the metal silicide layers 161 and the metal layers 163 can be ensured, such that the contact resistance can be reduced.

With further reference to FIG. 3, in one embodiment, the height of the diffusion barrier layers 162 on the side walls of the first recesses 167 in the third direction is ⅛-½ of the height of the metal layers 163 in the third direction. The ratio cannot be too large, which may still cause etching of the diffusion barrier layers 162 during etching of the capacitor holes, thereby causing a risk of contamination of the etching chamber, and the ratio cannot be too small, which may increase the process load and increase the process cost.

FIG. 4 illustrates enlarged views of capacitor contact structures in semiconductor structures in different embodiments.

Referring to FIG. 4, in one embodiment, orthographic projection areas of top surfaces of the metal layers 163 on the substrate 110 are smaller than orthographic projection areas of bottom surfaces of the metal layers 163 on the substrate 110. The bottom surfaces of the metal layers 163 are contact surfaces between the metal layers 163 and the diffusion barrier layers 162, and the top surfaces of the metal layers 163 are flat surfaces, that is, the top surfaces of the metal layers 163 are substantially parallel to the bottom surfaces of the metal layers 163. By setting the orthographic projection areas of the top surfaces of the metal layers 163 on the substrate 110 to be smaller than the orthographic projection areas of the bottom surfaces of the metal layers 163 on the substrate 110, with the miniaturization of the semiconductor structure, the risk of short circuit between the metal layers 163 can be reduced, and the electrical stability of the semiconductor structure can be improved.

With further reference to FIG. 4, in one embodiment, the metal layers 163 are provided with rounded corner structures a. That is, the rounded corner structures are arranged at tops or top corners of the metal layers, such that the electric field distribution can be improved, the intensity of a local electric field is reduced, and the possibility of dielectric breakdown is reduced. By using the rounded corner structures, the electric field is more uniform, which helps to extend the life and improve the reliability of the semiconductor structure.

With further reference to FIG. 2 or 3, in one embodiment, center lines of the active pillars 120 substantially overlap with center lines of the capacitor contact structures 160. The center lines of the active pillars 120 and the center lines of the capacitor contact structures 160 may completely overlap or may substantially overlap, i.e., with process errors. That is, the center lines of the active pillars 120 substantially overlap with the center lines of the capacitor contact structures 160, so as to ensure that the capacitor structures 170 are seated right above the active pillars 120, thereby obtaining a vertical channel transistor of a 4F2 (F denotes a minimum feature size) architecture. The area of the vertical channel transistor cell of the 4F2 architecture can be reduced by about 30% as compared to a planar transistor of a 6F2 architecture. Meanwhile, contact surfaces between the metal silicide layers 161 and the active pillars 120 are non-planar or non-flat surfaces, that is, the contact surfaces between the metal silicide layers 161 and the active pillars 120 may be curved surfaces, such that the contact area between the metal silicide layers 161 and the active pillars 120 may be increased, and the contact resistance between the metal silicide layers 161 and the active pillars 120 may be further reduced, which improves the transmission efficiency of the vertical channel transistor.

With further reference to FIG. 2 or 3, in one embodiment, orthographic projection areas of the first recesses 167 on the substrate 110 are larger than orthographic projection areas of the top surfaces of the active pillars 120 on the substrate 110. The top surfaces of the active pillars 120 are the contact surfaces between the active pillars 120 and the metal silicide layers 161, and the orthographic projection areas of the first recesses 167 on the substrate 110 depend on the maximum orthographic projection areas of the metal silicide layers 161, the diffusion barrier layers 162, and the metal layers 163 on the substrate 110, such that the top surfaces of the active pillars 120 can be completely exposed by the first recesses 167, the contact area between the active pillars 120 and the first recesses 167 is increased, and the contact resistance is reduced, which improves the transmission efficiency of the vertical channel transistor. Meanwhile, orthographic projection areas of the capacitor structures 170 on the substrate 110 are larger than orthographic projection areas of the capacitor contact structures 160 on the substrate 110, such that the contact area between the capacitor structures 170 and the capacitor contact structures 160 can be increased, and the contact resistance between the capacitor structures 170 and the capacitor contact structures 160 is reduced.

With further reference to FIG. 2 or 3, in one embodiment, source structures (not shown), vertical channels (not shown), and drain structures (not shown) are sequentially arranged on the active pillars 120 along the third direction, the source structures are located on tops of the active pillars 120; gate structures 130 are further formed in the substrate 110, the gate structures 130 surround portions of the active pillars 120, that is, the gate structures 130 surround channel regions of the active pillars 120. Referring to FIG. 1, adjacent ones of the gate structures 130 along the second direction, i.e., the X direction, are in contact connection to each other to form word lines, and adjacent ones of the gate structures 130 along the first direction, i.e., the Y direction, are insulated from each other. With further reference to FIG. 2 or 3, gate oxide layers 131 are further included between the gate structures 130 and the active pillars 120, and the gate oxide layers 131 may be of ring-shaped structures, that is, the gate oxide layers 131 surround the entire outer side walls of the channel regions of the active pillars 120. Alternatively, the gate oxide layers 131 may be of half ring-shaped structures, that is, the gate oxide layers 131 surround portions of the outer sidewalls of the channel regions of the plurality of active pillars 120, and other portions of the outer sidewalls of the channel regions may be exposed outside the gate oxide layers 131. The gate oxide layers 131 may be made of one or more of silicon oxide, fluorosilicate glass (FSG), borosilicate glass (BSG), phosphosilicate glass (PSG), or borophosphosilicate glass (BPSG). Bit line structures 140 are further formed in the substrate 110, the bit line structures 140 are located on a side of the substrate 110 away from the extension direction of the active pillars 120. Referring to FIG. 1, the bit line structures 140 extend along the first direction, i.e., the Y direction, and adjacent ones of the bit line structures 140 along the second direction, i.e., the X direction, are insulated from each other. Referring to FIG. 2 or 3, the bit line structures 140 are electrically connected to the active pillars 120, the bit line structures 140 are further isolated by isolation structures 152, the isolation structures 152 are located under the word line structures 130, and the isolation structures 152 may be made of one or more of silicon oxide, silicon nitride, silicon oxynitride, silicon oxycarbide, and silicon carbonitride. In addition, the bit line structures 140 are connected to first pads on the side of the substrate 110 away from the extension direction of the active pillars 120 through vias (not shown), so as to facilitate a subsequent bonding step.

On the basis of the above embodiments, an embodiment of the present disclosure further provides a semiconductor device. The semiconductor device will be described in detail below.

FIG. 5 illustrates a schematic structural view of a semiconductor device according to an embodiment of the present disclosure;

Referring to FIG. 5, in one embodiment, a semiconductor device 300 is obtained by bonding the above semiconductor structure 100 to a first wafer 200, the first wafer being provided with CMOS transistors of the semiconductor device. The semiconductor device 300 may be a memory device or a non-memory device. The memory device may include, for example, a dynamic random access memory (DRAM), a static random access memory (SRAM), a flash memory, an electrically erasable programmable read-only memory (EEPROM), a phase change random access memory (PRAM), or a magnetoresistive random access memory (MRAM). The non-memory device may be a logic device (e.g., a microprocessor, a digital signal processor, or a microcontroller) or the like. The first wafer 200 includes CMOS transistors and the like. For example, the first wafer 200 includes peripheral transistors and the like in the semiconductor device 300, such as the DRAM. The bonding method of the semiconductor structure 100 and the first wafer 200 may be bump bonding, fusion bonding, hybrid bonding, etc., and the bonding method of the semiconductor structure 100 and the first wafer 200 may also be chip-to-chip bonding or wafer-on-wafer bonding.

In one embodiment, the semiconductor structure 100 and the first wafer 200 may be bonded through hybrid bonding. Referring to FIG. 5, the semiconductor structure 100 leads internal electrical signals to first pads 101 through vias (not shown), the first wafer 200 leads internal electrical signals to second pads 201 through vias (not shown), the first pads 101 are isolated by a first dielectric layer 102, and the second pads 201 are isolated by a second dielectric layer 202. The hybrid bonding between the semiconductor structure 100 and the first wafer 200 is achieved through an annealing process. The first pads 101 and the second pads 201 may be made of the same material, such as a metal, for example, copper, gold, or aluminum. The first dielectric layer 102 and the second dielectric layer 202 may be made of the same material, such as an insulating material, for example, silicon nitride Si₃N₄, silicon dioxide SiO₂, silicon carbonitride SiCN, silicon oxynitride SiON, hafnium oxide HfO, or zirconium oxide ZrO.

On the basis of the above embodiments, an embodiment of the present disclosure further provides a method for manufacturing a semiconductor structure (hereinafter referred to as the manufacturing method), which is used for manufacturing the above semiconductor structure 100. The manufacturing method is described in detail below.

FIG. 6 illustrates a flowchart of steps for a method for manufacturing a semiconductor structure according to an embodiment of the present disclosure;

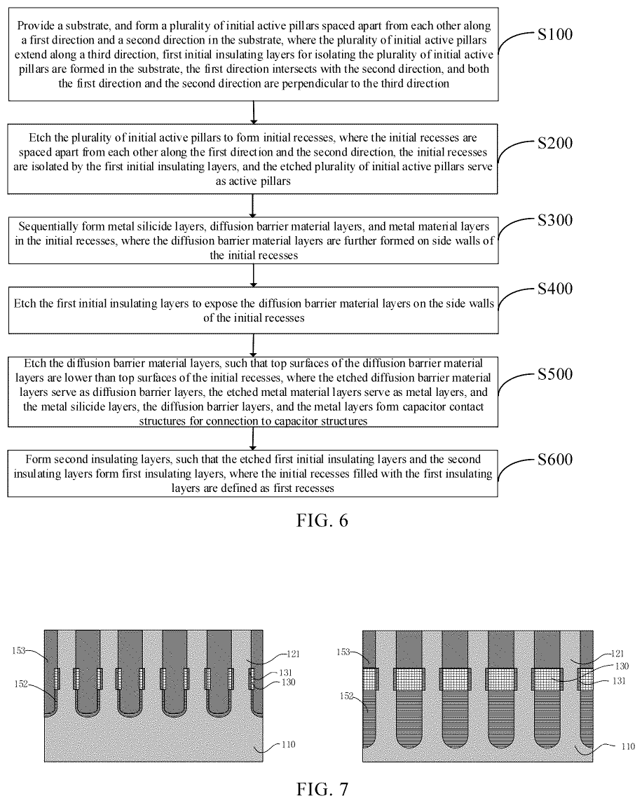

FIGS. 7-17 are cross-sectional views at a-a and c-c in FIG. 1 in the process of forming a corresponding semiconductor structure in some embodiments of the present disclosure.

Referring to FIG. 6, the method for manufacturing a semiconductor structure includes the following steps:

In S100, referring to FIG. 7, a substrate 110 is provided, and a plurality of initial active pillars 121 spaced apart from each other along a first direction and a second direction are formed in the substrate 110, where the plurality of initial active pillars 121 extend along a third direction, first initial insulating layers 153 for isolating the initial active pillars 121 are formed in the substrate 110, the first direction intersects with the second direction, and both the first direction and the second direction are perpendicular to the third direction.

Exemplarily, the first direction and the second direction may be perpendicular to each other, the first direction is, for example, the Y direction in FIG. 1, the second direction is, for example, the X direction in FIG. 1, and the third direction is, for example, the Z direction in FIG. 1, i.e., the thickness direction of the substrate 110. In other embodiments, the first direction and the second direction may not be perpendicular to each other. For example, an included angle between the first direction and the second direction may be an acute angle. The substrate 110 may be made of, for example, monocrystalline silicon, polycrystalline silicon, amorphous silicon, or silicon-on-insulator (SOI). In addition, the substrate 110 may be made of silicon germanium, silicon germanium-on-insulator (SGOI), indium antimonide, lead telluride compound, indium arsenide, indium phosphide, gallium arsenide, or gallium antimonide, but is not limited thereto. The plurality of initial active pillars 121 in the substrate 110 are spaced apart in an array and extend in the thickness direction of the substrate 110, i.e., the Z direction. The cross sections of the plurality of initial active pillars 121 may be circular, square, or oval, so as to improve the integration of the semiconductor structure 100, without being limited thereto. The first initial insulating layers 153 isolate the active pillars 120, and the first initial insulating layers 153 may be made of one or more of silicon oxide, silicon nitride, silicon oxynitride, silicon oxycarbide, or silicon carbonitride. In this embodiment, the first initial insulating layers 153 are made of silicon nitride, and the silicon nitride is low-density silicon nitride, so as to reduce the stress of the first initial insulating layers 153 on the initial active pillars 121.

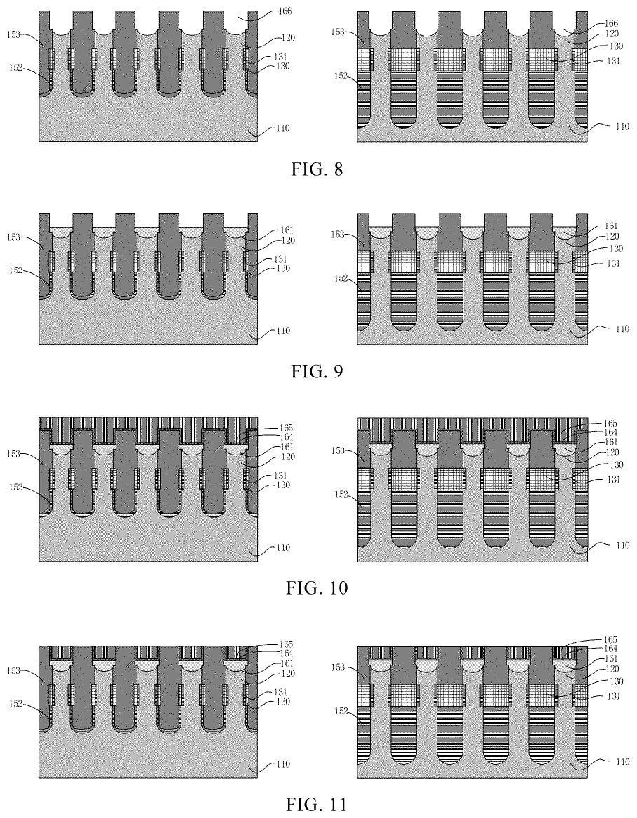

In S200, referring to FIG. 8, the initial active pillars 121 are etched to form initial recesses 166, where the initial recesses 166 are spaced apart from each other along the first direction and the second direction, the initial recesses 166 are isolated by the first initial insulating layers 153, and the etched initial active pillars 121 serve as active pillars 120.

In S300, referring to FIGS. 9-11, metal silicide layers 161, diffusion barrier material layers 164, and metal material layers 165 are sequentially formed in the initial recesses 166, where the diffusion barrier material layers 164 are further formed on side walls of the initial recesses 166.

Exemplarily, the metal silicide layers 161 are made of a compound formed by reacting a metal element (e.g., titanium, tungsten, nickel, cobalt, and molybdenum) with silicon, and the formation of the metal silicide produces a direct metal-semiconductor contact. The contact reduces the interface state, reduces the contact resistance, and improves the current transmission efficiency. Meanwhile, the metal silicide has good adhesion with silicon and the metal layers, which is beneficial to forming stable contact, reducing interface resistance, and improving the reliability of the whole circuit. Common metal silicides include titanium silicide (TiSi₂), tungsten silicide (WSi₂), nickel silicide (NiSi), cobalt silicide (CoSi₂), and the like. The diffusion barrier material layers 164 may prevent the metal material layers 165 from diffusing into the metal silicide layers 161, which may affect the electrical performance of the metal silicide layers 161. The diffusion barrier material layers 164 are made of a compound of metal titanium, such as titanium nitride (TiN), which has a high melting point and chemical stability, and can maintain its structural integrity at high temperatures, thereby effectively preventing the diffusion of metals into areas where their presence is undesirable. The metal material layers 165 are mainly made of a metal material, such as aluminum (Al), copper (Cu), and tungsten (W), which have low resistivity and can transmit current efficiently.

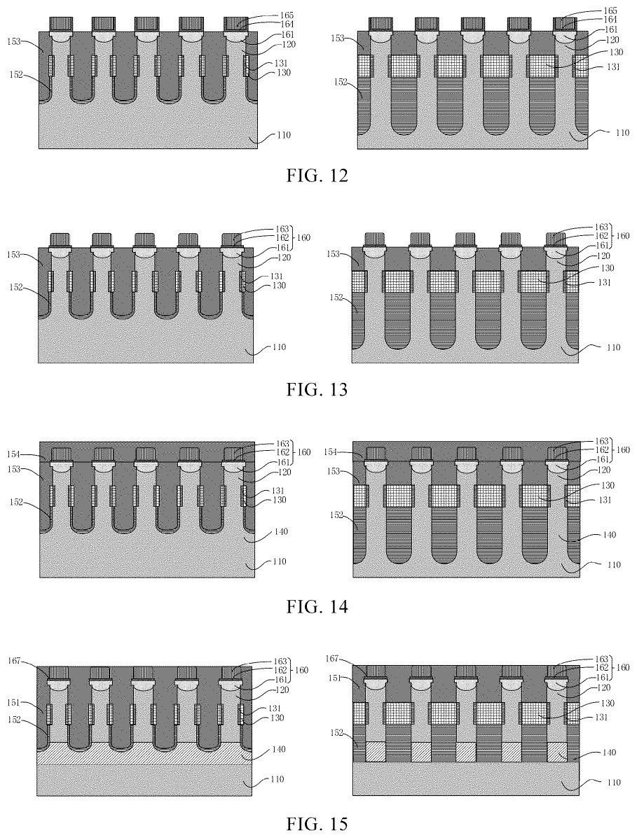

In S400, referring to FIG. 12 or 16, the first initial insulating layers 153 are etched to expose the diffusion barrier material layers 164 on the side walls of the initial recesses 166.

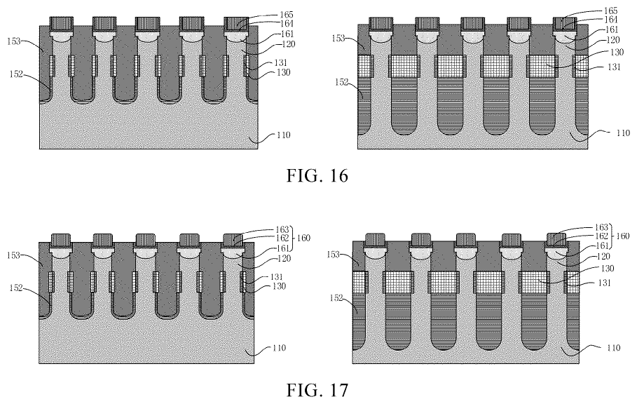

In S500, referring to FIG. 13 or 17, the diffusion barrier material layers 164 are etched, such that top surfaces of the diffusion barrier material layers 164 are lower than top surfaces of the initial recesses 166. Here, the top surfaces of the diffusion barrier material layers 164 are planes with the maximum height in the third direction. The etched diffusion barrier material layers 164 serve as diffusion barrier layers 162, the etched metal material layers 165 serve as metal layers 163, and the metal silicide layers 161, the diffusion barrier layers 162, and the metal layers 163 form capacitor contact structures 160 for connection to capacitor structures.

In S600, referring to FIGS. 14-15, second insulating layers 154 are formed, such that the etched first initial insulating layers 153 and the second insulating layers 154 form first insulating layers 151, where the initial recesses 166 filled with the first insulating layers 151 are defined as first recesses 167.

Referring to FIG. 12 or 16, in one embodiment, an exposure height in the third direction for exposing the diffusion barrier material layers 164 on the side walls of the initial recesses 166 is ½-⅞ of a height of the metal material layers 165 in the third direction. The ratio cannot be too small, which may still cause etching of the diffusion barrier layers 162 during etching of the capacitor holes, thereby causing a risk of contamination of the etching chamber, and the ratio cannot be too large, which may increase the load of the etching process and increase the cost of the etching process.

Referring to FIG. 8, in one embodiment, bottom surfaces of the initial recesses 166 are non-planar or non-flat surfaces, and orthographic projection areas of the initial recesses 166 on the substrate 110 are larger than orthographic projection areas of top surfaces of the active pillars 120 on the substrate 110. The bottom surfaces of the initial recesses 166 are non-planar or non-flat surfaces, such that contact surfaces between the metal silicide layers 161 and the active pillars 120 are non-planar or non-flat surfaces, that is, the contact surfaces between the metal silicide layers 161 and the active pillars 120 may be curved surfaces, such that the contact area between the metal silicide layers 161 and the active pillars 120 may be increased, and the contact resistance between the metal silicide layers 161 and the active pillars 120 may be further reduced, which improves the transmission efficiency of the vertical channel transistor. The orthographic projection areas of the initial recesses 166 on the substrate 110 are larger than the orthographic projection areas of the top surfaces of the active pillars 120 on the substrate 110. The top surfaces of the active pillars 120 refer to surfaces exposed by the initial recesses 166, such that the top surfaces of the active pillars 120 can be completely exposed by the initial recesses 166, such that the contact area between the active pillars 120 and the initial recesses 166 is increased, and the contact resistance is reduced, which improves the transmission efficiency of the vertical channel transistor.

In one embodiment, etching the first initial insulating layers 153 to expose the diffusion barrier material layers 164 on the side walls of the initial recesses 166 includes: an etch selectivity of the first initial insulating layers 153 to the diffusion barrier material layers 164 being greater than or equal to 5, and an etch selectivity of the first initial insulating layers 153 to the metal material layers 165 being greater than or equal to 6; and etching the diffusion barrier material layers 164 includes: an etch selectivity of the diffusion barrier material layers 164 to the first initial insulating layers 153 being greater than or equal to 6, and an etch selectivity of the diffusion barrier material layers 164 to the metal material layers 165 being greater than or equal to 6. Wet etching is used instead of dry etching when etching the first initial insulating layers 153 and etching the diffusion barrier material layers 164, as the wet etching generally has a better etch selectivity than the dry etching (such as reactive ion etching or plasma etching), such that the etching depth can be controlled more accurately by selecting the etch selectivity and controlling the etching time.

Referring to FIGS. 9-11, in one embodiment, sequentially forming the metal silicide layers 161, the diffusion barrier material layers 164, and the metal material layers 165 in the initial recesses 166 includes: forming the metal silicide layers 161 at bottoms of the initial recesses 166; continuing to deposit the diffusion barrier material layers 164, where the diffusion barrier material layers 164 cover the side walls of the initial recesses 166 and top surfaces of the metal silicide layers 161; depositing the metal material layers 165, where the metal material layers 165 cover the diffusion barrier material layers 164 and the first initial insulating layers 153; and performing a planarization process to expose the first initial insulating layers 153.

Referring to FIGS. 14-15, in one embodiment, forming the second insulating layers 154, such that the etched first initial insulating layers 153 and the second insulating layers 154 form the first insulating layers 151 includes: depositing the second insulating layers 154 to cover the metal layers 163 and the first initial insulating layers 153; and planarizing the second insulating layers 154 to expose the metal layers 163. The second insulating layers 154 may be made of one or more of silicon oxide, silicon nitride, silicon oxynitride, silicon oxycarbide, or silicon carbonitride. In this embodiment, the second insulating layers 154 and the first initial insulating layers 153 are made of the same material, i.e., silicon nitride. Meanwhile, the second insulating layers above the metal layers need to be removed, that is, the second insulating layers are removed by adopting a chemical mechanical polishing process, so as to make room for the subsequent deposition of supporting layers of the capacitor structures.

With the above manufacturing method, the metal silicide layers 161, the diffusion barrier layers 162, and the metal layers 163 may be sequentially laminated, such that the contact resistance between the active pillars and the capacitor structures of the vertical channel transistor can be effectively reduced, which improves the transmission rate of the vertical channel transistor. Meanwhile, portions or all of the diffusion barrier material layers on the side walls of the initial recesses are removed through etching, such that the top surfaces of the diffusion barrier material layers 164 are lower than the top surfaces of the initial recesses 166, such that titanium contamination of the etching chamber can be avoided in the process of etching the capacitor holes, thereby improving the precision of etching the capacitor holes.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, and the like indicate directional or positional relationships based on those shown in the drawings, merely for convenience of description of the present disclosure, and do not indicate or imply that the equipment or element referred to must have a particular direction, or be constructed and operated in a particular direction, and thus, are not to be construed as limiting the present disclosure.

In the description of the present disclosure, it should be understood that the terms “include” and “have” and any variations thereof, as used herein, are intended to cover non-exclusive inclusion. For example, a process, method, system, product, or apparatus including a series of steps or units is not necessarily limited to the explicitly listed steps or units, but may include other steps or units that are not explicitly listed or are inherent to such process, method, product, or apparatus.

Unless expressly stated or limited otherwise, the terms “mount”, “connect”, “link”, “fix”, and the like are to be construed in a broad sense. For example, it may be a fixed connection, a detachable connection, or integration; or may be a direct connection, an indirect connection by means of an intermediate, and an internal interconnection of two elements or an interaction of two elements. For those of ordinary skill in the art, the specific meaning of the above terms in the present disclosure may be understood according to the specific condition. In addition, the terms “first”, “second”, and the like, are only for the purpose of description, and may not be construed as indicating or implying the relative importance or implicitly indicating the number of technical features indicated.

Finally, it should be noted that: the above embodiments are merely used for illustrating the technical solutions of the present disclosure, rather than being limited; although the present disclosure has been described in detail with reference to the above embodiments, those of ordinary skill in the art will appreciate that: the technical solutions described in the foregoing embodiments may still be modified, or some or all of the technical features may be equivalently replaced; these modifications or replacements do not cause the essence of the corresponding technical solutions to depart from the scope of the technical solutions of the embodiments of the present disclosure.

1. A semiconductor structure, comprising:
a substrate, wherein a plurality of active pillars spaced apart from each other along a first direction and a second direction are arranged in the substrate, the plurality of active pillars extend along a third direction, first recesses exposing top surfaces of the plurality of active pillars are formed in the substrate, the first recesses are spaced apart from each other along the first direction and the second direction, first insulating layers are arranged in the substrate, the first insulating layers isolate the first recesses, the first direction intersects with the second direction, and both the first direction and the second direction are perpendicular to the third direction; and
capacitor contact structures, wherein the capacitor contact structures are located in the first recesses, and the capacitor contact structures cover the top surfaces of the plurality of active pillars for connection to capacitor structures, and
wherein the capacitor contact structures comprise metal silicide layers, diffusion barrier layers, and metal layers that are sequentially arranged in an extension direction of the plurality of active pillars, the metal silicide layers are in contact with the plurality of active pillars, and top surfaces of the diffusion barrier layers are lower than top surfaces of the first recesses.

2. The semiconductor structure according to claim 1, wherein the diffusion barrier layers are further arranged on side walls of the first recesses, and a height of the diffusion barrier layers on the side walls of the first recesses in the third direction is smaller than a height of the metal layers in the third direction.

3. The semiconductor structure according to claim 2, wherein the height of the diffusion barrier layers on the side walls of the first recesses in the third direction is ⅛-½ of the height of the metal layers in the third direction.

4. The semiconductor structure according to claim 1, wherein orthographic projection areas of top surfaces of the metal layers on the substrate are smaller than orthographic projection areas of bottom surfaces of the metal layers on the substrate.

5. The semiconductor structure according to claim 4, wherein the metal layers are provided with rounded corner structures.

6. The semiconductor structure according to claim 1, wherein center lines of the plurality of active pillars substantially overlap with center lines of the capacitor contact structures, and contact surfaces between the metal silicide layers and the plurality of active pillars are non-planar or non-flat surfaces.

7. The semiconductor structure according to claim 1, wherein orthographic projection areas of the first recesses on the substrate are larger than orthographic projection areas of the top surfaces of the plurality of active pillars on the substrate.

8. The semiconductor structure according to claim 1, wherein source structures, vertical channels, and drain structures are sequentially arranged on the plurality of active pillars along the third direction, and the source structures are located on tops of the plurality of active pillars; gate structures are further arranged in the substrate, the gate structures surround the vertical channels of the plurality of active pillars, adjacent ones of the gate structures along the second direction are in contact connection to each other, and adjacent ones of the gate structures along the first direction are insulated from each other; and bit line structures are further arranged in the substrate, the bit line structures are located on a side of the substrate away from the extension direction of the plurality of active pillars, the bit line structures extend along the first direction, and adjacent ones of the bit line structures along the second direction are insulated from each other.

9. A semiconductor device obtained by bonding the semiconductor structure according to claim 1 to a first wafer, the first wafer being provided with CMOS transistors of the semiconductor device.

10. A method for manufacturing a semiconductor structure, comprising:
providing a substrate, and forming a plurality of initial active pillars spaced apart from each other along a first direction and a second direction in the substrate, wherein the plurality of initial active pillars extend along a third direction, first initial insulating layers for isolating the plurality of initial active pillars are formed in the substrate, the first direction intersects with the second direction, and both the first direction and the second direction are perpendicular to the third direction;
etching the plurality of initial active pillars to form initial recesses, wherein the initial recesses are spaced apart from each other along the first direction and the second direction, the initial recesses are isolated by the first initial insulating layers, and the etched plurality of initial active pillars serve as active pillars;
sequentially forming metal silicide layers, diffusion barrier material layers, and metal material layers in the initial recesses, wherein the diffusion barrier material layers are further formed on side walls of the initial recesses;
etching the first initial insulating layers to expose the diffusion barrier material layers on the side walls of the initial recesses;
etching the diffusion barrier material layers, such that top surfaces of the diffusion barrier material layers are lower than top surfaces of the initial recesses, wherein the etched diffusion barrier material layers serve as diffusion barrier layers, the etched metal material layers serve as metal layers, and the metal silicide layers, the diffusion barrier layers, and the metal layers form capacitor contact structures for connection to capacitor structures; and
forming second insulating layers, such that the etched first initial insulating layers and the second insulating layers form first insulating layers, wherein the initial recesses filled with the first insulating layers are defined as first recesses.

11. The manufacturing method according to claim 10, wherein an exposure height in the third direction for the exposing the diffusion barrier material layers on the side walls of the initial recesses is ½-⅞ of a height of the metal material layers in the third direction.

12. The manufacturing method according to claim 10, wherein bottom surfaces of the initial recesses are non-planar or non-flat surfaces, and orthographic projection areas of the initial recesses on the substrate are larger than orthographic projection areas of top surfaces of the active pillars on the substrate.

13. The manufacturing method according to claim 10, wherein the etching the first initial insulating layers to expose the diffusion barrier material layers on the side walls of the initial recesses comprises: an etch selectivity of the first initial insulating layers to the diffusion barrier material layers being greater than or equal to 5, and an etch selectivity of the first initial insulating layers to the metal material layers being greater than or equal to 6; and
the etching the diffusion barrier material layers comprises: an etch selectivity of the diffusion barrier material layers to the first initial insulating layers being greater than or equal to 6, and an etch selectivity of the diffusion barrier material layers to the metal material layers being greater than or equal to 6.

14. The manufacturing method according to claim 10, wherein the sequentially forming the metal silicide layers, the diffusion barrier material layers, and the metal material layers in the initial recesses comprises: forming the metal silicide layers at bottoms of the initial recesses; continuing to deposit the diffusion barrier material layers, wherein the diffusion barrier material layers cover the side walls of the initial recesses and top surfaces of the metal silicide layers; depositing the metal material layers, wherein the metal material layers cover the diffusion barrier material layers and the first initial insulating layers; and performing a planarization process to expose the first initial insulating layers.

15. The manufacturing method according to claim 10, wherein the forming the second insulating layers, such that the etched first initial insulating layers and the second insulating layers form the first insulating layers comprises: depositing the second insulating layers to cover the metal layers and the first initial insulating layers; and planarizing the second insulating layers to expose the metal layers.
